(19) United States
(12) Patent Application Publication
(10) Pub. No.: US 2026/0060064 A1
(43) Pub. Date: Feb. 26, 2026

(54) APPARATUS WITH CIRCUIT INTERFACE FABRIC AND METHODS FOR OPERATING THE SAME

(71) Applicant: Micron Technology, Inc., Boise, ID (US)

(72) Inventors: Yasir Husain, Folsom, CA (US); Raymond Chang, Sacramento, CA (US); Raghukiran Sreeramaneni, Frisco, TX (US); Nevil N. Gajera, Meridian, ID (US); Timothy Langtry, San Jose, CA (US); Douglas Trujillo, Folsom, CA (US); Lingming Yang, Meridian, ID (US)

(21) Appl. No.: 19/287,292

(22) Filed: Jul. 31, 2025

Related U.S. Application Data
(60) Provisional application No. 63/687,093, filed on Aug. 26, 2024.

(51) Int. Cl. H01L 23/528; G11C 11/4093; H01L 21/768; H01L 23/48; H01L 25/18; H10B 80/00; H10D 80/30

(52) U.S. Cl. CPC H01L 23/528; G11C 11/4093; H01L 21/76898; H01L 23/481; H01L 25/18; H10B 80/00; H10D 80/30; H01L 2225/06517; H01L 2225/06541; H01L 2225/06565

(57) ABSTRACT

Methods, apparatuses, and systems related to a memory controller on an interface die and outside of a processor are described. Operations of the memory controller may be further facilitated by a circuit interface fabric configured to utilize separate write and read data buses within the interface die.

### CROSS-REFERENCE TO RELATED APPLICATION(S)

The present application claims priority to U.S. Provisional Patent Application No. 63/687,093, filed Aug. 26, 2024, the disclosure of which is incorporated herein by reference in its entirety.

### TECHNICAL FIELD

The disclosed embodiments relate to devices, and, in particular, to semiconductor memory devices with a circuit interface fabric and methods for operating the same.

### BACKGROUND

An apparatus (e.g., a processor, a memory system, and/or other electronic apparatus) can include one or more semiconductor circuits configured to store and/or process information. For example, the apparatus can include a memory device, such as a volatile memory device, a non-volatile memory device, or a combination device. Memory devices, such as dynamic random-access memory (DRAM), can utilize electrical energy to store and access data.

With technological advancements in embedded systems and increasing applications, the market is continuously looking for faster, more efficient, and smaller devices. To meet the market demands, the semiconductor devices are being pushed to the limit with various improvements. Improving devices, generally, may include increasing circuit density, increasing operating speeds or otherwise reducing operational latency, increasing reliability, increasing data retention, increasing functionalities, reducing power consumption, or reducing manufacturing costs, among other metrics.

### BRIEF DESCRIPTION OF THE DRAWINGS

FIG. 1A is a cross-sectional view of an example system-in-package (SiP) device.

FIG. 1B is a schematic block diagram of a processor and a memory device.

FIG. 1C is a circuit diagram of the processor and the memory device.

FIG. 2A is a cross-sectional view of a SiP device in accordance with an embodiment of the present technology.

FIG. 2B is a schematic block diagram of a processor and a memory device in accordance with an embodiment of the present technology.

FIG. 2C is a circuit diagram of the processor and the memory device of FIG. 2B in accordance with an embodiment of the present technology.

FIG. 3A is a timing diagram for the memory device of FIG. 1A.

FIG. 3B is a timing diagram for the memory device of FIG. 2A in accordance with an embodiment of the present technology.

FIG. 4A is a flow diagram illustrating an example method of manufacturing an apparatus in accordance with an embodiment of the present technology.

FIG. 4B is a flow diagram illustrating an example method of operating an apparatus in accordance with an embodiment of the present technology.

FIG. 5 is a schematic view of a system that includes an apparatus in accordance with an embodiment of the present technology.

### DETAILED DESCRIPTION

As described in greater detail below, the technology disclosed herein relates to an apparatus, such as for memory systems, systems with memory devices, related methods, etc., for providing a circuit interface fabric (e.g., a communications circuit that provides an interface between an on-die memory controller and off-die arrays). For example, the apparatus can include a High-Bandwidth Memory (HBM) device that includes one or more core dies stacked on an interface die. The interface die can include the circuit interface fabric that facilitates communication between a locally implemented memory controller (e.g., residing on/within the interface die) and the inter-die connections (e.g., Through Silicon Vias (TSVs)) that communicatively couple the core dies to the interface die.

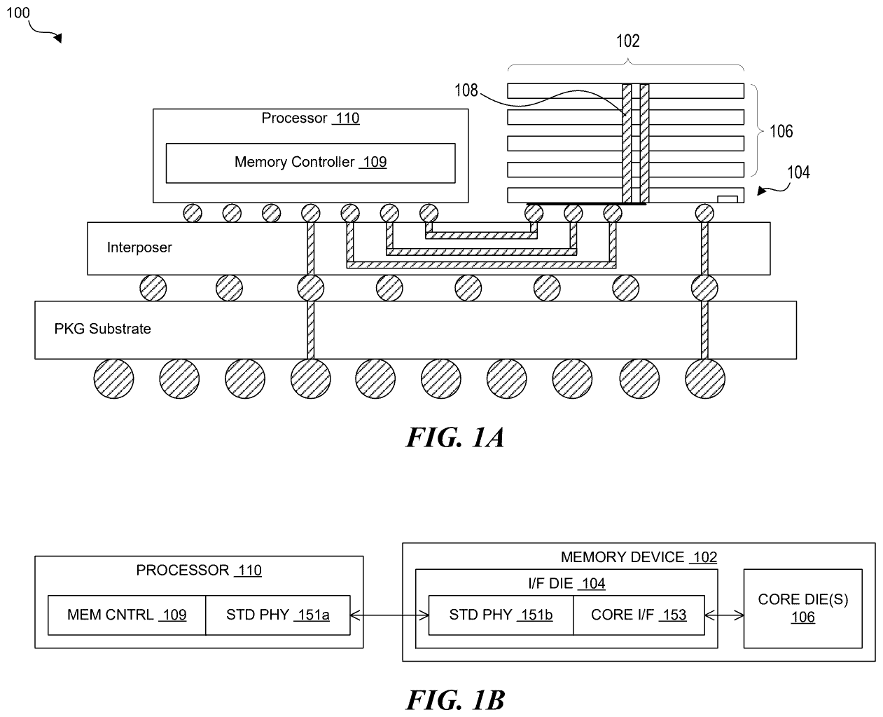

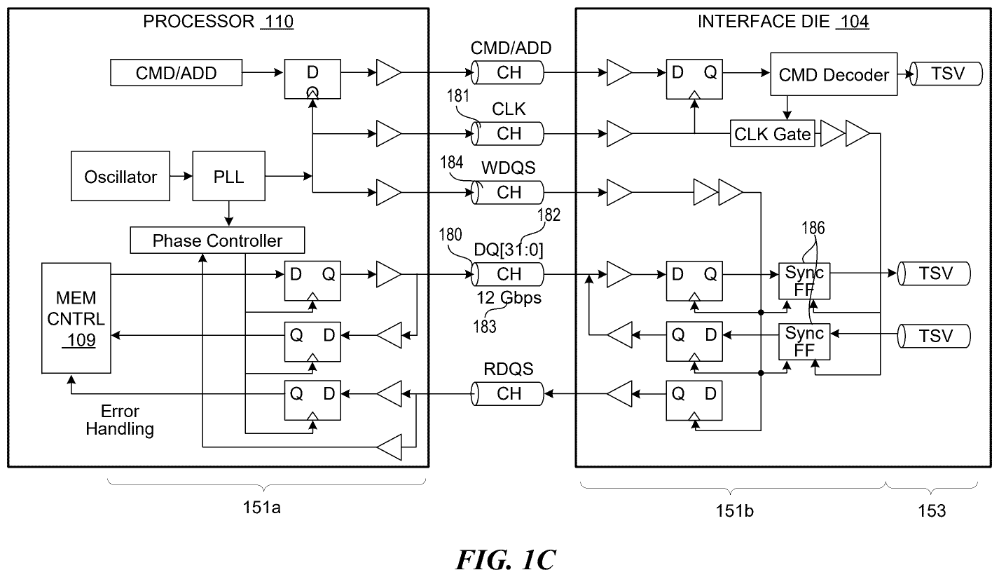

For context, conventional computing devices (e.g., a System-In-Package (SiP) devices) have the memory controller within a processor. FIG. 1 illustrates a schematic cross-sectional view of a SiP device 100. The SiP 100 can include a memory device 102 and a processor 110 (e.g., a central processing unit (CPU), a graphics processing unit (GPU), or the like), which are packaged together on a package substrate along with an interposer. The processor 110 may act as a host device of the SiP 100.

In some embodiments, the memory device 102 may be a HBM device that includes an interface die (or logic die) 104 and one or more memory core dies 106 stacked on the interface die 104. The memory core dies 106 can include DRAM devices/dies, NAND devices/dies, and/or other types of memory devices (e.g., static RAM (SRAM)) as main memory configured to store data provided by the processor 110 and to provide access of the stored data to the processor 110. The memory device 102 can further include additional and/or supplementary memory circuits (e.g., SRAM, DRAM, NAND, etc.), located within and/or outside of the core dies 106, configured for internal uses (e.g., remaining inaccessible to the processor 110). The memory device 102 can include one or more through silicon vias (TSVs) 108, which may be used to couple the interface die 104 and the core dies 106.

The processor 110 can further include a memory controller 109. In other words, the memory controller 109 can be external to the memory device 102. The memory controller 109 can include a circuit configured to control and manage the flow of data going to and from the memory device 102 and the processor 110. The memory controller 109 can manage memory mappings, such as between virtual and physical addresses, and perform the corresponding translations. Accordingly, the memory controller 109 can issue commands, such as reads, memory management functions (e.g., refresh), and/or the like, to the memory device 102 using the physical memory addresses. Moreover, the memory controller 109 can map the read data into virtual addresses so that the processor 110 can operate on the requested data (e.g., according to the virtual addresses).

Illustrating additional details of the memory controller 109, FIG. 1B is a schematic block diagram of a processor (e.g., the processor 110) and a memory device (e.g., the memory device 102). The processor 110 can include a physical layer (PHY) interface circuit 151a, such as transmitters, receivers, signal drivers, and/or the like, configured to facilitate the exchange of electrical signals with the memory device 102. The PHY 151a can be coupled to and controlled by the memory controller 109. For the SoC 100 (e.g., Artificial Intelligence (AI) processing devices) including the HBM, the PHY 151a can be configured according to Joint Electron Device Engineering Council (JEDEC) standards regarding HBM communications.

The PHY 151a can be coupled to the memory device 102 and the interface die 104 therein using channels or similar connections within the interposer. The interface die 104 can include a PHY circuit 151b that implements the communications for the memory device 102. Accordingly, the PHY 151b can match or correspond to the PHY 151a. For example, the PHY 151b can be configured according to the JEDEC HBM standards.

Internally, the PHY 151a can be coupled to the core dies 106 through a core interface 153, such as the TSVs 108 of FIG. 1A. Accordingly, the PHY 151a can further manage the communications to and from the core dies 106.

As a further detailed example, FIG. 1C is a circuit diagram of the processor 110 and the memory device 102 (e.g., the interface die 104 therein). The PHY 151a of FIG. 1B can correspond to the flip flops and the drivers, the phase-locked loop (PLL) circuit, the phase controller, and/or the oscillator in the processor 110.

The memory controller 109 (e.g., the DRAM controller) can provide the write data to the PHY 151a along with a corresponding command and address (CMD/ADD). The command and address can be communicated through corresponding channel(s) to a receiver circuit within the PHY 151b of the interface die 104. The PLL can provide a corresponding clock (CLK) 181 used to read the bits/transitions within the command and addresses. Further, the PLL and the Phase controller can provide a timing signal internal to the PHY 151a for driving the data (e.g., DQ) outputs, such as the data/payload targeted for the write. Using the timing signal, the PHY 151a can drive and send the write data over DQ channel(s) a DQ bus 180 to the PHY 151b of the interface die. In coordinating the communication/timing of the data, the PLL can further provide a write data strobe signal (WDQS) over corresponding channel(s) 184.

As described above, the PHY 151b can receive the command and address and the payload data associated with the write command. The PHY 151b can further receive the timing signals, such as the CLK and the WDQS. The PHY 151b can include receivers, flip flops, gates, decoders, and the like configured to receive and process the write command and data according to the timing signals. The command decoder can be configured to identify the physical location, such as the chip/core die indicated by the address and the location within the die (e.g., channel, bank, row, column, and/or the like). The command decoder can provide the corresponding notification (e.g., enable, address communication, and/or the like) to the targeted core die through corresponding TSV(s). The command decoder can further control and enable the receiver circuitry to receive the write data. The write data can be provided to the targeted die through corresponding TSV(s), and the targeted die can perform the internal operations to write the data at the commanded address. In internally communicating the write data, the PHY 151b can include synchronizing flip flops 186 configured to synchronize and align the WDQS with the CLK.

For read commands, the memory controller 109 can provide the read command and the targeted addresses similarly as for the write. The memory controller 109 can effectively trigger the PLL to provide the timing signals as described for the write.

In providing the read data back to the processor 110, the PHY 151b in the interface die can identify the targeted die and location within the targeted die, and the corresponding die can read back the information from the commanded location. The read data can be provided from the targeted core die to the interface die through corresponding TSVs. The PHY 151b can use the WDQS to time the communication of the read data and further provide a read data strobe signal (RDQS) over corresponding channel(s) to the PHY 151a. The synchronizing flip flops 186 can perform the alignment for the read data similarly as the write data.

The read data can be provided over the same channel(s) (e.g., the DQ bus 180 having a bus width 182 of [31:0] bits at a communication speed 183 of 12 Gbps per JEDEC HBM) as the write data. Stated differently, the PHY 151a and the PHY 151b can be connected through a bi-directional data bus used to communicate both the read data (e.g., to the PHY 151a) and the write data (to the PHY 151b).

To process the read data, the PHY 151b can include a receiver and a corresponding circuit path different from those of the write circuitry. The read data can be received according to the RDQS signal and provided to the memory controller 109.

### Example Environment

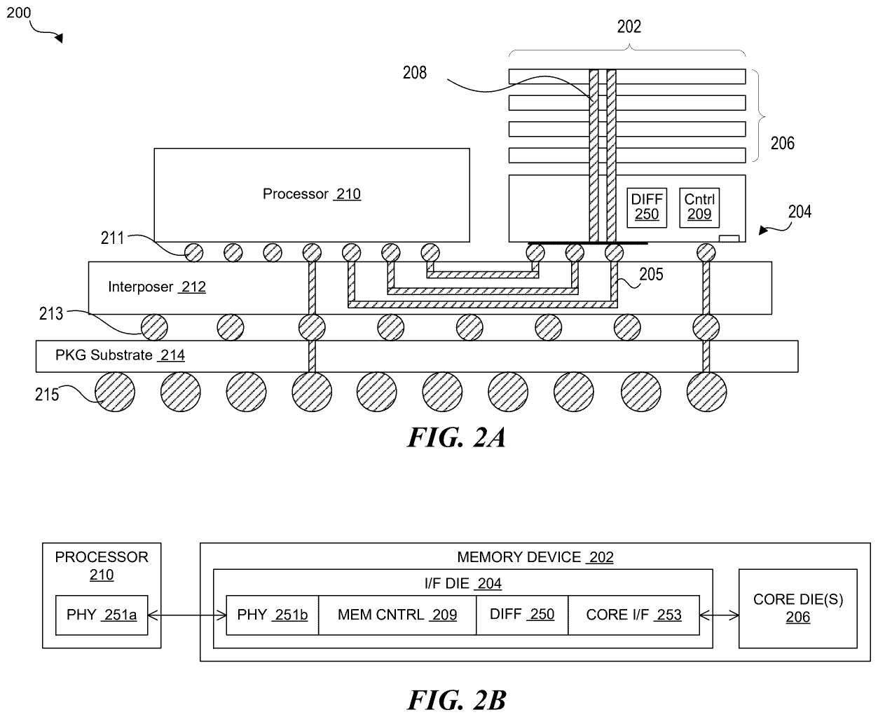

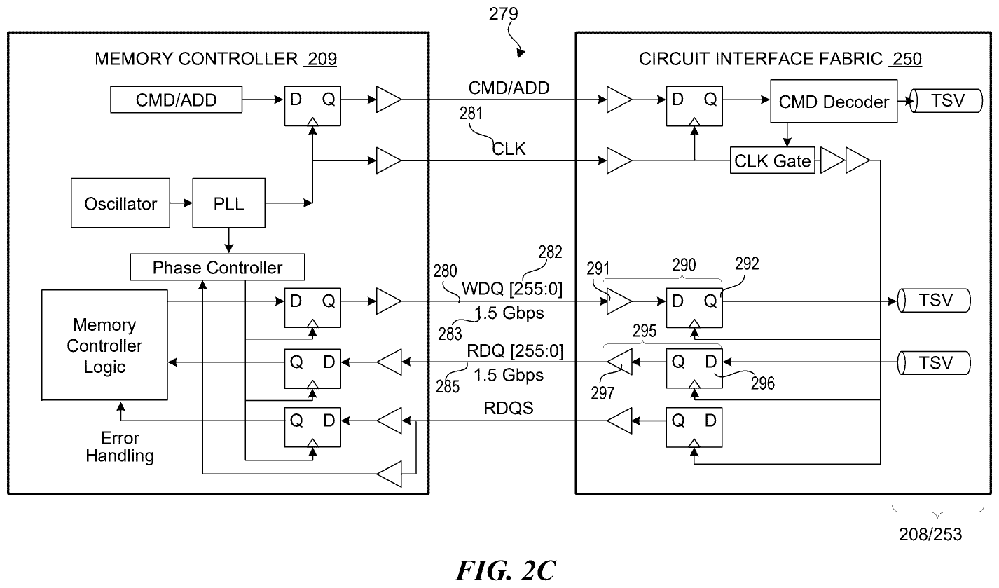

In contrast to the conventional computing devices, embodiments of the present technology can include the circuit interface fabric that enables the implementation of the memory controller within the memory device. To illustrate circuit interface fabric, the FIG. 2A is a cross-sectional view of a system-in-package (SiP) device 200 (i.e., an example apparatus) in accordance with embodiments of the technology. The SiP 200 can include a memory device 202 and a processor 210 (e.g., a CPU, a GPU, or the like), which are packaged together on a package substrate 214 along with an interposer 212. The processor 210 may act as a host device of the SiP 200.

In some embodiments, the memory device 202 may be a HBM device that includes an interface die (or logic die) 204 and one or more memory core dies 206 stacked on the interface die 204. The memory core dies 206 can include DRAM devices/dies, NAND devices/dies, and/or other types of memory devices (e.g., SRAM) as main memory configured to store data provided by the processor 210 and to provide access of the stored data to the processor 210. The memory device 202 can further include additional and/or supplementary memory circuits (e.g., SRAM, DRAM, NAND, etc.), located within and/or outside of the core dies 206, configured for internal uses (e.g., remaining inaccessible to the processor 210). The memory device 202 can include one or more TSVs 208, which may be used to couple the interface die 204 and the core dies 206.

The interposer 212 (e.g., a silicon interposer) can provide electrical connections between the processor 210, the memory device 202, and/or the package substrate 214. For example, the processor 210 and the memory device 202 may both be coupled to the interposer 212 by a number of internal connectors (e.g., micro-bumps 211). The interposer 212 may include channels 205 (e.g., an interfacing or a connecting circuit) that electrically couple the processor 210 and the memory device 202 through the corresponding micro-bumps 211. While three channels 205 are shown in FIG. 2, greater or fewer numbers of channels 205 may be used. The interposer 212 may be coupled to the package substrate by one or more additional connections (e.g., intermediate bumps 213, such as C4 bumps).

The package substrate 214 can provide an external interface for the SiP 200. The package substrate 214 can include external bumps 215, some of which may be coupled to the processor 210, the memory device 202, or both. The package substrate may further include direct access (DA) bumps coupled through the package substrate 214 and interposer 212 to the interface die 204.

Unlike the SiP 100 of FIG. 1A, the SiP 200 can include a memory controller 209 within the memory device 202 instead of the processor 210. For the illustrated example, the interface die 204 can include the memory controller 209. The memory controller 209 can be generally similar to the memory controller 109 of FIG. 1, such as the overall function. In some embodiments, the memory controller 209 can be different, such as regarding separate write and read circuit paths/connections, and the details of such differences are described further below.

Additionally, to further facilitate the functions of the memory controller 209 within the memory device 202, the memory device 202 can include a circuit interface fabric 250. In some embodiments, the circuit interface fabric 250 can include a DRAM Interface Fabric (DIFF) circuit on the interface die 204. The circuit interface fabric 250 can include circuitry, electrical connections, and/or arrangements thereof configured to facilitate communications between the processor 202 and the core dies 206 through the TSVs 208.

### Interface Fabric

To further illustrate the circuit interface fabric 250, FIG. 2B is a schematic block diagram of a processor (e.g., the processor 210) and a memory device (e.g., the memory device 202) in accordance with an embodiment of the present technology. The processor 210 can include a physical interface (PHY) circuit 251a, such as transmitters, receivers, signal drivers, and/or the like, configured to facilitate the exchange of electrical signals with the memory device 102. Unlike the PHY 151a of FIG. 1B, the PHY 251a can controlled by the processor 210 (e.g., the logic therein). Differing from the PHY 151a implemented in HBM applications, the PHY 151a can have a device-to-device (D2D) PHY interface configuration (i.e., different from JEDEC HBM configuration). In some embodiments, the D2D PHY 151a can have a custom configuration. In other embodiments, the D2D PHY 151a can have a standard configuration (e.g., Universal Chiplet Interconnect Express (UCIe)).

The PHY 251a can be coupled to the memory device 202 and the interface die 204 therein using channels (e.g., the channels 205 of FIG. 2A) or similar connections within the interposer 212 of FIG. 2. The interface die 204 can include a PHY circuit 251b that implements the communications for the memory device 202. Accordingly, the PHY 251b can match or correspond to the PHY 251a. For example, the PHY 251b can be configured according to the D2D PHY interface configuration instead of the JEDEC HBM standards.

The memory controller 209 can be configured to control the communications between the PHY 251b and the circuit interface fabric 250. The memory controller 209 can utilize PHY 251b for communicating with the PHY 251a and utilize the circuit interface fabric 250 for internally communicating with the core dies 206 through core interface 253 (e.g., the TSVs 208 of FIG. 2A).

FIG. 2C illustrates further details of the circuit interface fabric 250. FIG. 2C is a circuit diagram of the processor and the memory device in accordance with an embodiment of the present technology. As described above, the memory controller 209 can have similar components as the PHY 151a of FIG. 1C that are implemented in the interface die 204 of FIG. 2A. Further, the memory controller can be connected to the circuit interface fabric 250 using die-internal connections 279 that differ from the connections between the PHY 151a and the PHY 151b of FIG. 1C. The circuit interface fabric 250 can include the signal connection points and circuit paths, electrical components within the circuit paths, arrangement of the components, connections to the TSVs, or a combination thereof.

While the data for the memory controller 109 were communicated through die-external connections (e.g., the channels within the interposer of FIG. 1A) with the processor 110 of FIG. 1A, the data for the circuit interface fabric 250 can be communicated over the die-internal connections 279. For the HBM applications, the connection between the memory controller 209 and the circuit interface fabric 250 can differ from the JEDEC HBM requirements. In some embodiments, the DQ channel can include a dedicated write connections (e.g., unidirectional write DQ or WDQ bus 280) separate from dedicate read connections (e.g., unidirectional read DQ or RDQ bus 285) instead of the bidirectional DQ bus 180 of FIG. 1C. Accordingly, the memory controller 209 and the circuit interface fabric 250 can each include corresponding circuit paths 291 and 295 and internal connections. The separate RDQ bus 285 and the WDQ bus 280 can provide reduced Read to Write Bus Turnaround time (tRTW) since separate dedicated circuits are utilized for the corresponding unidirectional connections.

In some embodiments, the WDQ bus 280 and the RDQ bus 285 can each have a bus width 282 (e.g., a number of parallel connections) greater than the bidirectional DQ bus 180. In comparison to the bus width 182 of FIG. 1C of 32 for JEDEC HBM DQs, the circuit interface fabric 250 in the example illustrated in FIG. 2A can have the bus width 282 of 256 (e.g., [255:0]). Accordingly, to achieve the same throughput, the circuit interface fabric 250 can utilize a burst length (BL) lower than that of the bidirectional DQ bus 180. For example, the BL for the WDQ bus 280 and the RDQ bus 285 can be 1 in comparison to the BL of 8 for the JEDEC HBM bidirectional DQ bus 180. Stated differently, the circuit interface fabric 250 can facilitate a more parallel communication across the wider write and read buses in comparison to the more serial communications of the JEDEC HBM DQs.

The wider connections of the circuit interface fabric 250 and/or the corresponding memory controller 209 can further enable a communication speed 283 that is lower than the communication speed 183 of FIG. 1C, such as from 12 Gbps of the JEDEC interface to 1.5 Gbps, to achieve the same throughput (e.g., 3 TB/s). Thus, the wider bus connections of the circuit interface fabric 250 and/or the corresponding memory controller 209 can allow longer time windows to process each bit, thereby reducing errors and power consumptions typically associated with higher frequency signal processing.

Regarding the different timing signals, the circuit interface fabric 250 can coordinate or time the write data using the CLK signal instead of the WDQS signal 184 of FIG. 1C based on the separate read and write buses. Accordingly, the circuit interface fabric 250 eliminate the WDQS clock domain in view of the CLK domain. Further, by eliminating the WDQS domain, the synchronizing flip flops (FFs) 186 of FIG. 1C can be eliminated from the communication chain. In other words, the circuit interface fabric 250 can directly provide the write data to the corresponding TSVs using the CLK signal and without the synchronization required for JEDEC HBM write communications.

As an illustrative example, the circuit interface fabric 250 can include (1) a set of write receiver circuits 290 configured to receive the write data from the controller 209 over the WDQ bus 280 and (2) a set of read transmitter circuits 295 configured to send the read data to the controller 209 over the RDQ bus 285. Each of the write receiver circuits 290 can include (a) a signal detector 291 (e.g., an op amp or a similar signal receiver) receiving the electrical signals representative of the write data and (b) a bit identifier 292 (e.g., a flip flop) configured to identify bit values associated with the received electrical signal. The bit identifier 292 can operate directly based on the CLK 181 (e.g., without alignment or processing with another signal, such as the WDQS) to sample the incoming signal and provide an output bit stream directly to the TSVs 208. Similarly, each of the read transmitter circuits 295 can include a bit identifier 296 operating directly based on the CLK 181 and with a signal transmitter 297 to generate signals representative of the read data.

### Timing Diagrams

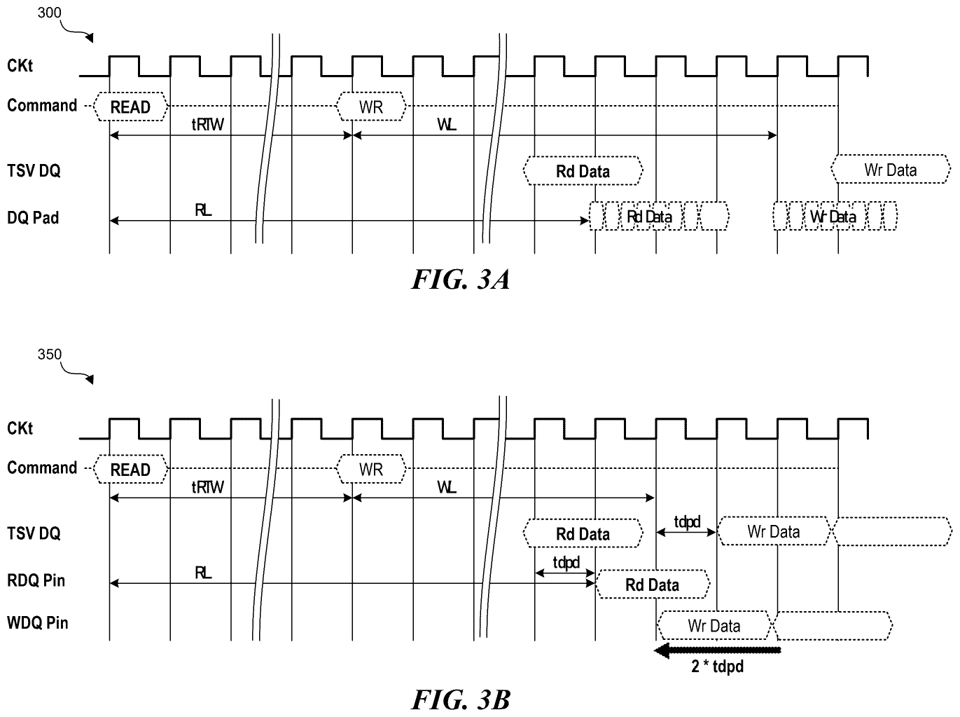

To illustrate the different operations, FIG. 3A is a timing diagram 300 for the memory device 102 of FIG. 1A while FIG. 3B is a timing diagram 350 for the memory device 202 of FIG. 2A in accordance with an embodiment of the present technology. For the memory device 102, the memory controller 109 of FIG. 1A can provide a read command and a write command separated in time by a minimum delay (e.g., tRTW). At the interface die 104 of FIG. 1B, the read command can process through the PHY 151b, and as a result, the read data can arrive at a DQ TSV (e.g., a connection to the TSV connecting to the core dies 106 of FIG. 1A) at a later time. The PHY 151a can provide the read data through the DQ pads a predetermined time afterwards (e.g., a set number of CKt cycles). The write data can arrive at the DQ pads through the same bidirectional DQ connections after communicating the read data. The PHY 151b can provide the write data to the DQ TSV after a predetermined duration.

In facilitating the reads and writes, the tRTW may be required to have a minimum duration to ensure that there is no clash between the read data and the write data on the DQ connections. For example, tRTW may be required to be greater than a combination of read latency (RL), BL (e.g., in number of CKS), write latency (WL), and DQ channel turnaround time, such as according to tRTW>RL+BL+DQ Channel Turnaround Time−WL.

In contrast, the timing diagram 350 shows the circuit interface fabric 250 of FIG. 2B and the corresponding sets of separate unidirectional RDQS and WDQS providing independent or separate communication of read data and write data. When the memory device 202 receives the same read and write commands as shown in the timing diagram 300, the read data can arrive at the same time at the DQ TSV and the RDQ pin as compared to the timing diagram 300. However, the PHY 251b of FIG. 2B and the circuit interface fabric 250 can provide direct communication of the bits instead of the burst-based communication of the PHY 151b. Further, given the separate RDQS and WDQS, the memory device 202 (e.g., the core dies 206) can be configured to provide the write data at the DQ TSV after a data path delay from TSV DQ to RDQ/WDQ pin (tdpd). Thus, the write data can be provided earlier to the TSV DQ, and the write data can be provided over the WDQ pin earlier. Given the separate communicative connections, the write data may partially overlap the read data in time.

The tRTW for the unidirectional DQs may be required to be long enough to ensure no clash occurs on the DQ TSV, which may remain bidirectional. The tRTW can be expressed based on a combination of RL, read/write bank A to read/write bank B command delay (tCCDS) and the DQ TSV bus turnaround time, such as according to tRTW>RL+tCCDS+TSV DQ Bus Turnaround Time−WL−2tdpd. As a result, the tRTW for the circuit interface fabric 250 can be reduced by 2*tdpd based on the unidirectional DQ connections and further reduced since TSV DQ Bus Turnaround time is faster than DQ channel Turnaround Time.

Additionally, the circuit interface fabric 250 can allow the memory controller 209 to be offloaded from the processor 210 and onto the interface die 204, thereby allowing the processor 210 to use the freed up space for other computational circuits. Moreover, the circuit interface fabric 250 can allow increased resources, such as the increased DQ channel capacity, in facilitating the communication between the memory controller 209 and the TSVs 208, thereby increasing the signal processing window through a slower sampling clock while maintaining the required throughput. The circuit interface fabric 250 can simplify the timing requirements, such as using 1.5 Gbps through the wider DQ bus in comparison to the 12 Gbps for the bidirectional JEDEC HBM standard. Moreover, the simplified timing requirements can reduce the circuit complexity for the related communication circuits, which further reduces the power consumption associated with the previously required advanced I/O schemes. Also, as mentioned above, the circuit interface fabric 250 can remove the synchronization FFs and WDQS CLK path, thereby eliminating any need for WDQS-to-CK alignment training and further reducing the related circuitry and power consumption on the interface die 204.

### Control Flow

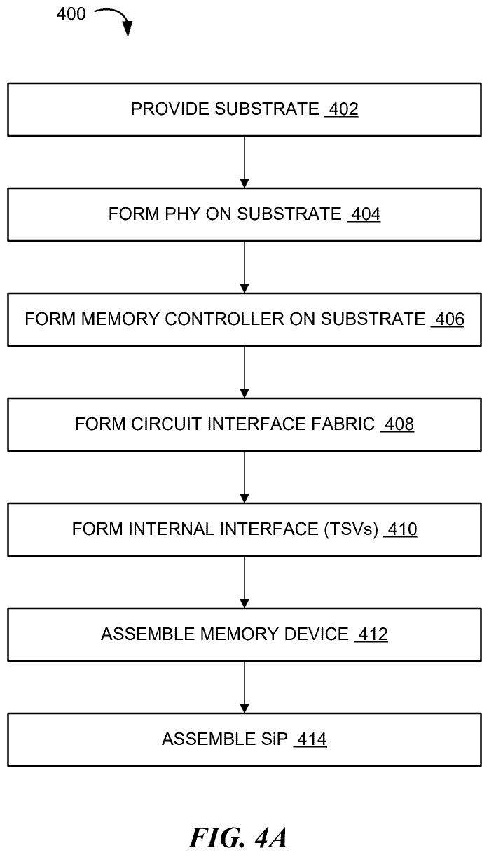

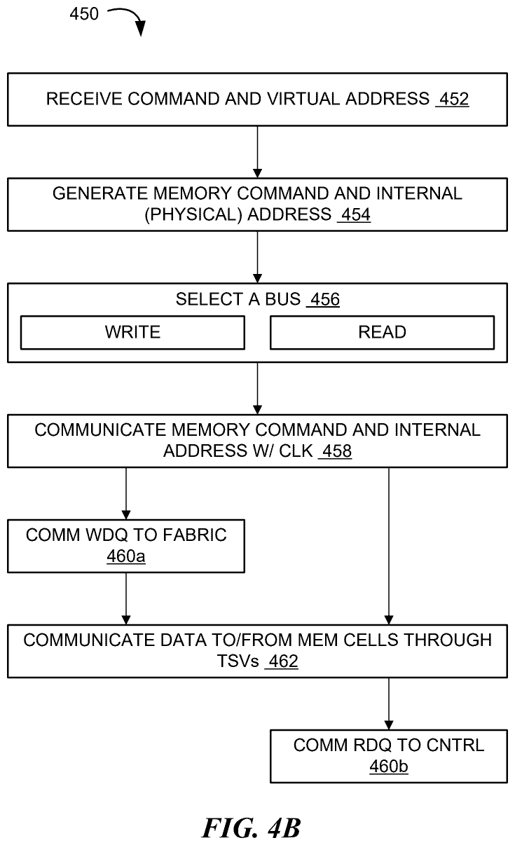

FIG. 4A is a flow diagram illustrating an example method 400 of manufacturing an apparatus (e.g., the SiP 200 of FIG. 2A, the memory device 202 of FIG. 2A, and/or the interface die 204 of FIG. 2A,) in accordance with an embodiment of the present technology. The method 400 can include manufacturing the circuit interface fabric 250 of FIG. 2A, the memory controller 209 of FIG. 2A or both on the interface die 204 and/or a corresponding device or SiP.

At block 402, the method 400 can include providing a semiconductor substrate, such as a semiconductor wafer. The semiconductor wafer can be processed to form functional circuitry thereon, such as active components, passive components, electrical connections, power components, and/or the like. At block 404, the method 400 can include forming the PHY 251b configured to communicate signals with an externally located processor (e.g., the processor 210 of FIG. 2A) for implementing writes to locations in the core dies 206 of FIG. 2A and reads from the locations in the dies 206. As described above, the formed PHY 251b can have a D2D communication configuration that is different from the JEDEC HBM requirements for communications between the PHY 151a of FIG. 1B and the PHY 151b of FIG. 1B.

At block 406, the method 400 can include forming a memory controller circuit (e.g., the memory controller 209) coupled to the PHY and configured to control and manage flow of data between the processor and memory cells. The memory controller 209 can have dedicated read connections and corresponding circuit paths separate from dedicated write connections/circuit paths.

At block 408, the method 400 can include forming a circuit interface fabric (e.g., the circuit interface fabric 250) connected to the memory controller. Forming the circuit interface fabric can include forming the die-internal connections 279 of FIG. 2C. Accordingly, the method 400 can include forming the WDQ bus 280 of FIG. 2C, the RDQ bus 285 of FIG. 2C, and the connection for the CLK 281 of FIG. 2C. The WDQ bus 280 and the RDQ bus 285 can each be unidirectional for communicating the write data and the read data, respectively.

The WDQ bus 280 and the RDQ bus 285 can each have the bus width 282 of FIG. 2C that is greater than that of the JEDEC HBM bidirectional DQ standardized bus width 182 of FIG. 1C. For example, the bus width 282 can be 33 bit width or greater (e.g., 256 bit width). Further, the circuit interface fabric 250 can utilize the communication speed 283 of FIG. 2C that is less than the standardized communication speed 183 of FIG. 1C for the JEDEC HBM communication. For example, the communication speed 283 can be less than 12 Gbps (e.g., 1.5 Gbps) for communicating data with the memory controller 209.

To facilitate the WDQ bus 280 and the RDQ bus 285, the circuit interface fabric 250 can be formed with the set of write receiver circuits 290 of FIG. 2C and the set of set of read transmitter circuits 295. The circuits 290 and 295 can be configured to operate directly based on the CLK 281 without adjusting/aligning with the WDQS 184 of FIG. 1C. Accordingly, the circuit interface fabric 250 can be formed without the synchronizing FFs 186 of FIG. 1C.

At block 410, the method 400 can include forming TSVs (e.g., the TSVs 208 of FIG. 2A as an example of the core interface 253 of FIG. 2B) connected to the circuit interface fabric. The TSVs can be formed coupling the WDQ connection point and the RDQ connection point to the core dies 206 having the memory cells and stacked on the HBM interface die 204. The TSVs can be directly connected to the write receiver circuits 290 and the read transmitter circuits 295 without intervening circuitry (e.g., the synchronizing FFs 186).

At block 412, the method 400 can include assembling a memory device (e.g., the memory device 202) using the processed substrate. The memory device can be formed by stacking the memory dies 206 over the interface die 204. In some embodiments, the memory device can be formed by stacking and bonding the wafers (e.g., the wafers having the memory circuits over the wafer having the interface circuits) and then singulating the wafer stack to form the singulated die stacks.

At block 414, the method 400 can include assembling a SiP or a portion thereof using the memory device. For example, the method 400 can include attaching the memory device 202 over the interposer 212 of FIG. 2A, mounting the processor 210 over the interposer 212, mounting the interposer 212 over the package substrate 214 of FIG. 2A, or a combination thereof.

FIG. 4B is a flow diagram illustrating an example method 450 of operating an apparatus (e.g., the SiP 200 of FIG. 2A, the memory device 202 of FIG. 2A, the interface die 204 of FIG. 2A, etc.) in accordance with an embodiment of the present technology. The method 450 can be for operating the circuit interface fabric 250 of FIG. 2A, the memory controller 209 of FIG. 2A or a combination thereof internal to the interface die 204.

At block 452, the method 450 can include receiving a command and an associated virtual address from the processor 210 of FIG. 2A. The memory controller 209 can receive the command and the virtual address from the processor 210 through the PHY 251b of FIG. 2B (e.g., the D2D communication interface).

At block 454, the method 450 can include generating memory command and internal/physical address based on the command and virtual address. The memory controller 209 can use the memory mapping (e.g., page table) to generate an internal memory command, such as a read command or a write command, and the corresponding physical address for a location within the core dies 206 of FIG. 2A.

At block 456, the method 450 can include selecting a bus according to the command. The controller 209 can select a bus for communicating the data associated with the generated command. For example, the memory controller 209 can enable the WDQ bus 280 of FIG. 2C for the write command or the RDQ bus 285 of FIG. 2C for the read command.

At block 458, the method 450 can include communicating memory command and internal address with the CLK to the circuit interface fabric 250. The memory controller 209 can communicate the generated memory command and the interna/physical address to the circuit interface fabric 250. The memory controller 209 can communicate the command and address over the corresponding CMD/ADD connection of FIG. 2C. The memory controller 209 can send the CLK 281 over the corresponding connection.

At block 460a, when the commanded operation is a write operation, the method 450 can include communicating the write data to the circuit interface fabric 250. The memory controller 209 can send the targeted write data over the corresponding dedicated unidirectional bus (e.g., the WDQ) to the circuit interface fabric 250.

At block 462, the method 450 can include communicating the data to/from the memory cells through the internal interface (e.g., TSVs). The circuit interface fabric 250 can communicate the targeted data between the circuit path and the internal interface 253. For the write command, the circuit interface fabric 250 can communicate the received write data from the write receiver circuits 290 of FIG. 2C to the TSVs 208. For the read command, the circuit interface fabric 250 can communicate the read data from the TSVs 208 to the read transmitter circuits 295.

At block 460b, when the commanded operation is a read operation, the method 450 can include communicating the read data from the circuit interface fabric 250 to the memory controller 209. The circuit interface fabric 250 can send the targeted read data over the corresponding dedicated unidirectional bus (e.g., the RDQ) to the memory controller 209.

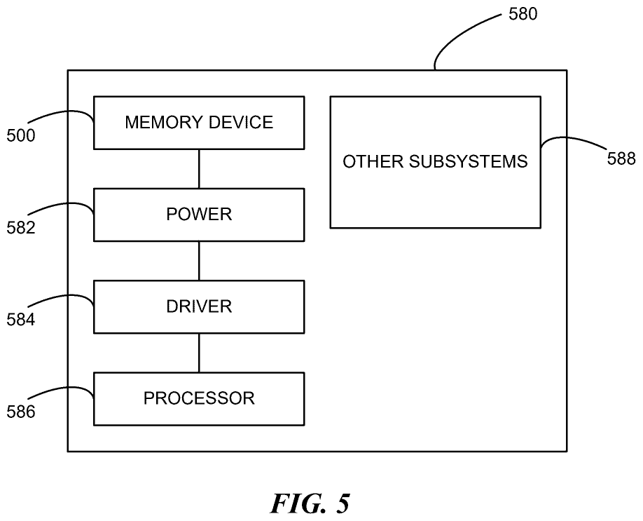

FIG. 5 is a schematic view of a system that includes an apparatus in accordance with embodiments of the present technology. Any one of the foregoing apparatuses (e.g., memory devices) described above with reference to FIGS. 2A-C, 3B, 4A, and 4B can be incorporated into any of a myriad of larger and/or more complex systems, a representative example of which is system 580 shown schematically in FIG. 5. The system 580 can include a memory device 500, a power source 582, a driver 584, a processor 586, and/or other subsystems or components 588. The memory device 500 can include features generally similar to those of the apparatus described above with reference to FIGS. 1, 3, 4A, and 4B, and can therefore include various features for performing a direct read request from a host device. The resulting system 580 can perform any of a wide variety of functions, such as memory storage, data processing, and/or other suitable functions. Accordingly, representative systems 580 can include, without limitation, hand-held devices (e.g., mobile phones, tablets, digital readers, and digital audio players), computers, vehicles, appliances and other products. Components of the system 580 may be housed in a single unit or distributed over multiple, interconnected units (e.g., through a communications network). The components of the system 580 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of DRAM devices. Apparatuses configured in accordance with other embodiments of the present technology, however, can include other types of suitable storage media in addition to or in lieu of DRAM devices, such as, devices incorporating NAND-based or NOR-based non-volatile storage media (e.g., NAND flash), magnetic storage media, phase-change storage media, ferroelectric storage media, etc.

The term “processing” as used herein includes manipulating signals and data, such as writing or programming, reading, erasing, refreshing, adjusting or changing values, calculating results, executing instructions, assembling, transferring, and/or manipulating data structures. The term data structure includes information arranged as bits, words or code-words, blocks, files, input data, system-generated data, such as calculated or generated data, and program data. Further, the term “dynamic” as used herein describes processes, functions, actions or implementation occurring during operation, usage or deployment of a corresponding device, system or embodiment, and after or while running manufacturer's or third-party firmware. The dynamically occurring processes, functions, actions or implementations can occur after or subsequent to design, manufacture, and initial testing, setup or configuration.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to FIGS. 2A-C, 3B, 4A, 4B, and 5.

I/We claim:

1. A High-Bandwidth Memory (HBM) interface die configured to be stacked with one or more core memory dies, the HBM interface die comprising:
a physical layer interface circuit (PHY) configured to communicate signals with a processor for implementing writes to locations in the core memory dies and reads from the locations in the memory dies,
wherein the PHY has a device-to-device (D2D) communication configuration different from a JEDEC HBM communication configuration;
a set of Through Silicon Vias (TSVs) communicatively coupled to the PHY and configured to provide vertical communicative connections to the core memory dies;
a memory controller located between and coupled to the PHY and the TSVs within the interface die, the memory controller configured to control and manage flow of data between the processor and the core memory dies for the read and write operations; and
a circuit interface fabric connecting the memory controller to the TSVs, the circuit interface fabric connected using a set of dedicated write data connections (WDQ) and a set of dedicated read DQ connections (RDQ) respectively configured for communicating write data and read data between the memory controller and the core memory dies through the TSVs.

2. The HBM interface die of claim 1, wherein each of the WDQ and the RDQ of the circuit interface fabric has a bus width greater than a standardized bus width of the JEDEC HBM communication configuration for communicating read and write data between the processor and the interface die.

3. The HBM interface die of claim 2, wherein the circuit interface fabric uses a communication speed for communicating the write data and the read data respectively over the WDQ and the RDQ, wherein the communication speed is less than a standardized speed for the JEDEC HBM communication configuration for communicating read and write data between the processor and the interface die.

4. The HBM interface die of claim 3, wherein the each of the bus width is 256 and the communication speed is 1.5 Gbps.

5. The HBM interface die of claim 1, wherein the circuit interface fabric includes:
a set of write receiver circuits configured to receive the write data from the memory controller, wherein the set of write receiver circuits is directly connected to the TSVs for directly providing the write data to the TSVs; and
a set of read transmitter circuits configured to send the read data to the memory controller, wherein the set of read transmitter circuits is directly connected to the TSVs for directly receiving the read data from the TSVs.

6. The HBM interface die of claim 5, wherein:
the circuit interface fabric is configured to receive a clock signal (CLK) from the memory controller;
the set of write receiver circuits is configured to receive the write data directly based on the CLK. and without aligning the CLK with a separate write data strobe (WDQS).

7. The HBM interface die of claim 6, wherein:
the set of write receiver circuits is directly connected to the TSVs without synchronizing flip flops (FFs) between the set of write receiver circuits and the TSVs; and
each receiver circuit in the set of write receiver circuits includes a signal detector and a bit identifier,
wherein the signal detector is configured to receive an electrical signal representative of the write data,
wherein the bit identifier is configured to identify bit values corresponding to the received signal based on sampling the received electrical signal directly according to the CLK.

8. A High-Bandwidth Memory (HBM) device comprising:
at least one core die configured to store data; and
an interface die stacked with the core die, the interface die including:
an external communication interface configured to communicate signals with an externally located processor;
an internal communication interface communicatively coupled to the external communication interface and configured to provide communicative connections to the stacked core die;
a memory controller coupled to the internal and external communication interfaces and configured to control and manage flow of data between the processor and the core dies; and
a circuit interface fabric connecting the memory controller to the internal communication interface, the circuit interface fabric including (1) write data connections (WDQ) and (2) read DQ connections (RDQ) respectively configured for communicating write data and read data between the memory controller and the internal communication interface.

9. The HBM device of claim 8, wherein each of the WDQ and the RDQ has a bus width greater than a standardized bus width of a JEDEC HBM communication configuration for communicating data with the processor.

10. The HBM device of claim 8, wherein each of the WDQ and the RDQ has a bus width of 33 or greater.

11. The HBM device of claim 8, wherein the circuit interface fabric uses a communication speed for communicating the write data and the read data respectively over the WDQ and the RDQ, wherein the communication speed is less than a standardized speed for a JEDEC HBM communication configuration for communicating data with the processor.

12. The HBM device of claim 8, wherein the circuit interface fabric uses a communication speed less than 12 Gbps for communicating the write data and the read data respectively over the WDQ and the RDQ.

13. The HBM device of claim 8, wherein the WDQ and the RDQ are each configured for unidirectional communications.

14. The HBM device of claim 8, wherein the circuit interface fabric includes:
a set of write receiver circuits configured to receive the write data from the memory controller, wherein the set of write receiver circuits is directly connected to the internal communication interface; and
a set of read transmitter circuits configured to send the read data to the memory controller, wherein the set of read transmitter circuits is directly connected to the internal communication interface.

15. The HBM device of claim 14, wherein the set of write receiver circuits is configured to receive the write data directly based on a clock signal (CLK) from the memory controller and independent and/or without a write data strobe (WDQS).

16. The HBM device of claim 14, wherein:
the internal communication interface includes Through Silicon Vias (TSVs) coupling the circuit interface fabric to memory cells in the at least one core die; and
the set of write receiver circuits and the set of read transmitter circuits are each directly connected to the TSVs without an intervening circuitry there between.

17. A method of manufacturing a High-Bandwidth Memory (HBM) interface die, the method comprising:
providing a semiconductor substrate;
forming a physical layer interface circuit (PHY) configured to communicate signals with an externally located processor;
forming a memory controller circuit coupled to the PHY and configured to control and manage flow of data between the processor and memory cells;
forming a circuit interface fabric connected to the memory controller, the circuit interface fabric including a write data (WDQ) connection point and a read data (RDQ) connection point; and
forming Through Silicon Vias (TSVs) connected to the circuit interface fabric, the TSVs configured to couple the WDQ connection point and the RDQ connection point to a memory die having the memory cells and stacked on the HBM interface die.

18. A method of operating a High-Bandwidth Memory (HBM) device, the method comprising:
receiving a processor command and a virtual address from an externally located processor for a memory operation;
generating, at a memory controller in the HBM device, a memory command and an internal address based on the received processor command and the virtual address;
communicating a target data over a dedicated unidirectional bus, the target data corresponding to the memory command and the internal address; and
communicating the target data between the dedicated unidirectional bus and a set of memory cells corresponding to the internal address over an internal interface.

19. The method of claim 18, wherein:
the memory command is for a read operation or a write operation;
the dedicated unidirectional bus includes a unidirectional write data (WDQ) bus or a unidirectional read data (RDQ) bus; and
communicating the target data includes selecting the WDQ bus or the RDQ bus corresponding to the memory command.

20. The method of claim 18, further comprising:
communicating a clock signal (CLK) from the memory controller for coordinating communication timing, wherein the target data for a write command is communicated directly based on the CLK and independent of a write data strobe (WDQS).
